(19) United States
(12) Patent Application Publication
(10) Pub. No.: US 2026/0042662 A1
(43) Pub. Date: Feb. 12, 2026

(54) PACKAGED MEMS DEVICE HAVING A HUMIDITY SENSOR

(71) Applicant: STMicroelectronics International N.V., Geneva (CH)

(72) Inventors: Luca Giuseppe FALORNI, Limbiate (MB) (IT); Federico MORELLI, Milano (IT); Roberto CARMINATI, Piancogno (IT)

(73) Assignee: STMicroelectronics International N.V., Geneva (CH)

(21) Appl. No.: 19/283,711

(22) Filed: Jul. 29, 2025

(30) Foreign Application Priority Data
Jul. 31, 2024 (IT) 102024000017911

(51) Int. Cl. B81B 7/02; B81C 99/00

(52) U.S. Cl. CPC B81B 7/02; B81C 99/003; B81B 2201/0235; B81B 2201/0242; B81B 2201/0292; B81B 2203/04; B81B 2207/015; B81B 2207/07

(57) ABSTRACT

Packaged MEMS device having a MEMS die of semiconductor material formed by a sensor body and a cap mutually bonded. The sensor body incorporates at least one MEMS component and the cap carries a humidity sensor having a first and a second group of electrodes, facing each other and capacitively coupled, configured to provide a humidity signal. A packaging mass, of electrically insulating material, surrounds the MEMS die and the humidity sensor.

### TECHNICAL FIELD

The present invention relates to a packaged MEMS device having a humidity sensor.

For example, the following description refers to inertial sensors such as gyroscopes and accelerometers, without however being limited thereto.

### BACKGROUND

As is known, MEMS devices, in particular MEMS devices that implement inertial sensors such as gyroscopes and accelerometers, are usually packaged in a housing of insulating material protecting them from external environmental influences, as well as mechanically protecting and electrically insulating them.

The housing may be made by using different technologies. For example, LGA (Land Grid Array) packages, made by molding a resin mass, are often used to package inertial sensors. This packaging is very widespread since it is cheap, easy to make and able to provide reasonable protection in most cases.

However, this technique does not ensure absolute impermeability to water droplets.

Consequently, in presence of high humidity or, worse, exposure to liquids, some droplets may easily penetrate the housing.

This is disadvantageous, since humidity may cause deformations of both the housing (generating mechanical stress states on the sensor) and the same MEMS sensor, as visible by comparing FIGS. 1 and 2, schematically showing a section through a packaged MEMS device 1.

In detail, the packaged MEMS device 1 shown in FIGS. 1 and 2 comprises a support 2, for example a plastic substrate; a first die 3 integrating a signal processing circuit, for example an ASIC (Application Specific Integrated Circuit), hereinafter also simply referred to as ASIC die 3, attached to the support 2; a second die 4 integrating a micro-electro-mechanical, MEMS, system and hereinafter also simply referred to as MEMS die 4, attached to the first die 3; and a packaging mass 5, for example of resin, surrounding the first and the second dice 2, 3 and the exposed upper surface of the support 2.

FIG. 1, in particular, shows the packaged MEMS device 1 in the undeformed state; FIG. 2 shows the effect of water droplets 8 that penetrate the packaging mass 5 and cause a deformation of both the packaging mass 5 and the underlying structures (support 2, first and second dice 3, 4).

In particular, the stress induced on the MEMS die 4 and the deformations of the same MEMS die 4 may cause errors in the output signals of the MEMS die 4, for example drifts in the reference values, such as the ZRL—Zero Rate Level—value of gyroscopes or the ZGO—Zero Gravity Offset—value of accelerometers, which negatively impact the sensor performances.

To solve this problem, it has already been proposed to associate a humidity sensor to MEMS devices.

However, current commercial humidity sensors have large dimensions, not compatible with those of current MEMS devices. For example, for comparison, typical dimensions of commercial sensors may be of several centimeters, to be compared with millimetric dimensions of MEMS devices. Current humidity sensors cannot therefore be integrated in a same housing with the MEMS die.

The aim of the present invention is to provide a packaged MEMS device incorporating a humidity sensor.

### SUMMARY

According to the present invention, a packaged MEMS device having a humidity sensor, a method of calibrating a packaged MEMS device and a method of compensating an output signal of a packaged MEMS device are provided, as defined in the appended claims.

### BRIEF DESCRIPTION OF THE DRAWINGS

For a better understanding of the present invention, embodiments thereof are now described, purely by way of non-limiting example, with reference to the attached drawings, wherein:

FIG. 1 is a schematic cross-section of an undeformed packaged MEMS device;

FIG. 2 is a schematic cross-sectional view of the packaged MEMS device of FIG. 1, in a deformed condition;

FIG. 3 is a top perspective view of the present packaged MEMS device, wherein the package is shown in-ghost;

FIG. 4 is a cross-sectional view of the packaged MEMS device of FIG. 3;

FIG. 5 is a cross-sectional view of the present packaged MEMS device, according to another embodiment;

FIGS. 6-10 show the plot of quantities relative to the present packaged MEMS device, during test steps;

FIG. 11 is a schematic cross-sectional view of the present packaged MEMS device in presence of humidity and with a compensation unit;

FIG. 12 is a flow chart of a characterization step of the present packaged MEMS device;

FIGS. 13 and 14 show the plot of quantities relative to the present packaged MEMS device for compensating the drift of the measured quantities due to humidity; and

FIG. 15 is a flow chart relative to a compensation step of the present packaged MEMS device.

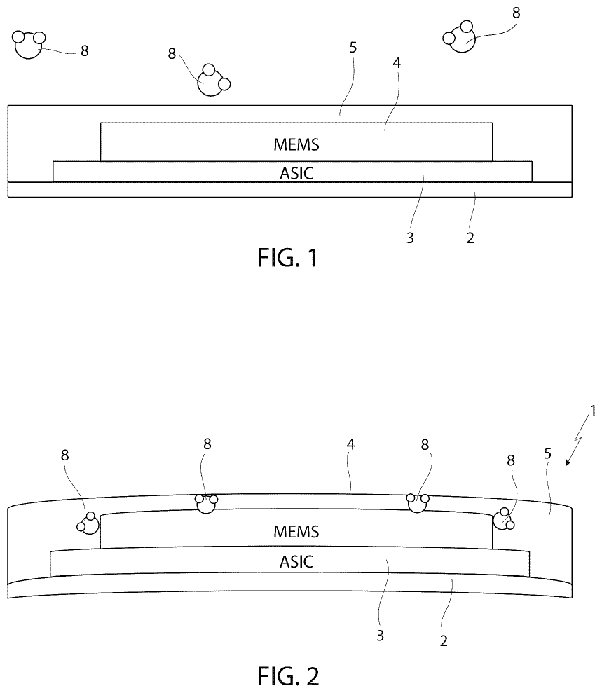

### DESCRIPTION OF EMBODIMENTS

The following description refers to the arrangement shown; consequently, expressions such as “above”, “below”, “upper”, “lower”, “right”, “left” relate to the attached Figures and are not to be interpreted in a limiting manner.

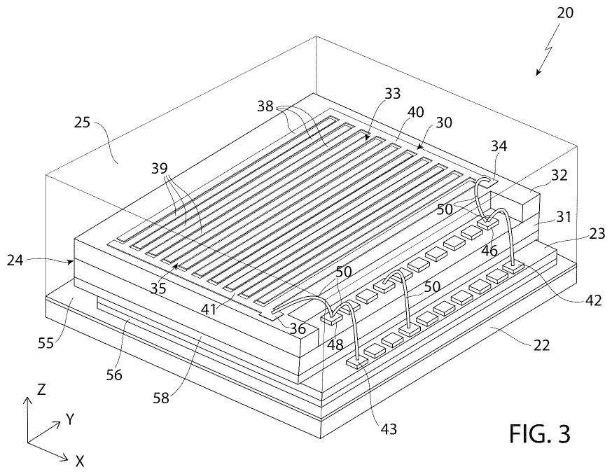

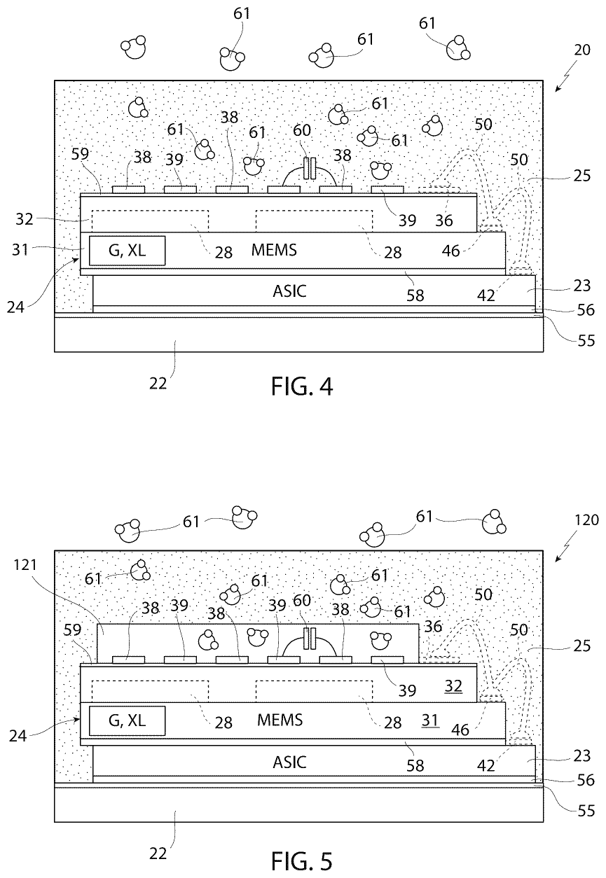

FIGS. 3 and 4 show a MEMS device 20.

MEMS device 20 comprises a support 22, for example a plastic substrate; a first die 23 of semiconductor material, such as silicon, integrating a signal processing circuit, for example an ASIC (Application Specific Integrated Circuit), hereinafter also simply referred to as ASIC die 23; a second die 24 of semiconductor material, such as silicon, integrating a MEMS—micro-electro-mechanical—system and hereinafter also simply referred to as MEMS die 24; a humidity sensor 30, formed above the MEMS die 24; and a packaging mass 25 (shown in ghost in FIG. 3), of electrically insulating material, for example of resin.

The packaging mass 25 surrounds the first and the second dice 23, 24 as well as the humidity sensor 30 and covers the exposed upper surface of the support 22.

In particular, the MEMS device 20 forms an LGA (Land Grid Array) package.

In detail, the ASIC die 23 is attached to the support 22 and forms a processing unit that cooperates with the MEMS die 24 executing the tasks envisaged for the MEMS device 20; for example, it receives signals correlated to the displacements of the movable parts of the MEMS die 24 and processes them to obtain position, speed and acceleration information, provided externally. Hereinafter, therefore the term “displacement” means “variation of the measured quantity” or “output of the MEMS die” (e.g. acceleration in case of an accelerometer, angular speed in case of a gyroscope).

The MEMS die 24 is attached to the ASIC die 23 and comprises a sensor body 31 and a cap 32.

The sensor body 31 is formed from a first wafer and integrates one or more inertial sensors, such as a gyroscope and an accelerometer having one or more axes, schematically represented in FIG. 4. In particular, in a manner not shown and known to the person skilled in the art, the sensor body 31 comprises fixed parts, integral with the MEMS die 24, movable parts, subject to displacements in presence of external accelerations, and detection structures, configured to generate corresponding displacement signals.

The cap 32 is generally formed from a second wafer, different from the first wafer and is bonded to the sensor body 31; for example, bonding may occur at a wafer level or after dicing the MEMS die 24, in a manner known per se.

The cap 32 may also have one or more cavities facing a respective sensor integrated in the sensor body 31; the cavity/ies (28 in FIGS. 4 and 5) may be set at a controlled pressure, lower than the atmospheric one, and/or contain particular gases, in a manner know to the person skilled in the art. In case of multiple cavities, they may be at different pressure.

The cap 32 may be electrically coupled to the mass potential of the MEMS die 24, in a manner known per se.

The humidity sensor 30 is formed on the cap 32 and is of a capacitive type, formed by electrodes of conductive material (typically a metal such as aluminum), facing each other.

In detail, the humidity sensor 30 comprises a first group of electrodes 33 coupled to a first sensor pad 34, and a second group of electrodes 35, coupled to a second sensor pad 36.

The groups of electrodes 33, 35 may each comprise one or more electrodes.

In particular, in the embodiment shown, the first group of electrodes 33 comprises a plurality of first electrodes 38 and the second group of electrodes 35 comprises a plurality of second electrodes 39, where the first electrodes 38 are interdigitated with the second electrodes 39.

For example, the first and the second electrodes 38, 39 may be formed by equal metal stripes, separated from each other by a gap, whose mutual capacitive facing is detectable by the ASIC die 23.

In particular, in case of a MEMS die 24 having area 3×3 mm², the first and the second electrodes 38, 39 may have elongated rectangular shape, with a length of 2.5 mm, width comprised between 10 and 20 μm, gap of 5-10 μm. In this manner, about 80 strips (80 electrodes between first and second electrodes 38, 39) are obtained.

Furthermore, in case of interdigitated rectangular electrode configuration represented in FIGS. 3 and 4, a first arm 40 extends transversely to the first electrodes 38 and is coupled to one end thereof; it is also coupled, at one own end, to the first sensor pad 34.

A second arm 41 extends transversely to the second electrodes 39 and is coupled to one end thereof; it is also coupled, at one own end, to the second sensor pad 36.

The first and the second sensor pads 34, 36 are coupled to a first, respectively a second ASIC pad 42, 43 on the ASIC die 23.

In particular, in the embodiment shown, the sensor pads 34, 36 are indirectly coupled to the respective ASIC pads 42, 43.

Precisely, the first sensor pad 34 is coupled to a first MEMS pad 46 formed on the upper surface of the sensor body 31, in a recessed zone of the cap 32, and the first MEMS pad 46 is coupled to the first ASIC pad 42; the second sensor pad 36 is coupled to a second MEMS pad 48 formed on the upper surface of the sensor body 31 and the second MEMS pad 48 is coupled to the second ASIC pad 43.

The couplings between the sensor pads 34, 36 and the MEMS pads 46, 48 as well as between the MEMS pads 46, 48 and the ASIC pads 42, 43 occur through wires 50.

FIG. 3 also shows further MEMS pads 51 coupled to respective further ASIC pads 52 arranged on the ASIC die 23 through wires 50.

Furthermore, a first insulating layer 55 extends on the support surface 22; a first bonding layer 56 (for example a “die attach” layer) extends between the first insulating layer 55 and the ASIC die 23; a second bonding 58 (for example a “die attach” layer) extends between the ASIC die 23 and the MEMES die 24; and a second insulating layer 59 (not shown in FIG. 3, but visible in FIG. 4) extends above the MEMS die 24, between the latter and the humidity sensor 30. The second insulating layer 59 is, for example, of silicon oxide.

The humidity sensor 30 may be directly covered by the packaging mass 25, as shown in FIG. 4, or may be covered by a humidity sensitive layer, as shown in FIG. 5.

In detail, FIG. 5 shows a MEMS device 120 having the general structure of the MEMS device 20 of FIG. 4 (therefore the common elements are indicated with the same reference numbers), where a humidity sensitive layer 121 covers the humidity sensor 30, leaving exposed the sensor pads 34, 36 (whereof in FIG. 4 only the first sensor pad 36 is represented with a dashed line).

The humidity sensitive layer 121 may be for example of polyimide, with a thickness comprised between 1 and 20 μm.

FIGS. 4 and 5 show the capacitive coupling between the first and the second electrodes 38, 39, represented by a capacitor 60, and the presence of water droplets 61 penetrated from the outside of the MEMS device 20, 120 and absorbed both by the packaging mass 25 and (for the MEMS device 120 of FIG. 5) by the humidity sensitive layer 121.

In FIGS. 4 and 5 the second insulating layer 59 is also visible and the wires 50 and the MEMS 48 and ASIC pads 43 have been represented in dashed line.

Furthermore, in FIGS. 4 and 5, by way of example, the sensor body 31 of the MEMS die 23 integrates a gyroscope G and an accelerometer XL.

The MEMS device 20, 120 is formed following the usual MEMS manufacturing techniques; in particular, before or after dicing the ASIC 23 and MEMS dice 24, the second insulating layer 59 is deposited on the surface of the cap 32 and the humidity sensor 30 is formed by depositing and photolithographically defining a metal layer, so as to form the first and the second arms 40, 41, the first and the second electrodes 38, 39, the first and the second sensor pads 34, 36.

Then, wire 50 connections are formed as well as connections to the outside (not shown) and the packaging mass 25 is molded, possibly after forming the humidity sensitive layer 121.

In MEMS devices 20 and 120, when they are exposed to humidity, they may absorb water droplets 61. For example, studies by the Applicant have shown that the resin usually used for packaging is able to absorb water up to 14% of its weight.

Similarly, the polyimide of the humidity sensitive layer 121 has relatively high absorption properties.

When water droplets 61 penetrate within the packaging mass 25 (and possibly the humidity sensitive layer 121), they cause a change in the dielectric constant Er of the layer (25, 121) interposed between the first group of electrodes 33 and the second group of electrodes 35, changing the capacitance of the humidity sensor 30.

The capacitance variation undergone by the humidity sensor 30 may therefore be used as a measure of humidity.

On the other hand, the presence of humidity in the MEMS device 20, 120 causes a deformation of the same MEMS device 20, which may influence the reliability of the measures carried out.

The Applicant has carried out studies that have shown the existence of a correlation between the level of humidity present (and measurable with the humidity sensor 30) and the deformation undergone; such correlation may therefore be exploited to compensate the measures acquired by the MEMS device 20, 120.

In particular, studies by the Applicant have shown that, in some situations, the capacitance modification of the humidity sensor 30 is approximately proportional to the amount of absorbed water.

To this end, a test MEMS device formed as the MEMS device 20 has been introduced in a test environment where a humidity level that is controlled and increasing over time has been created.

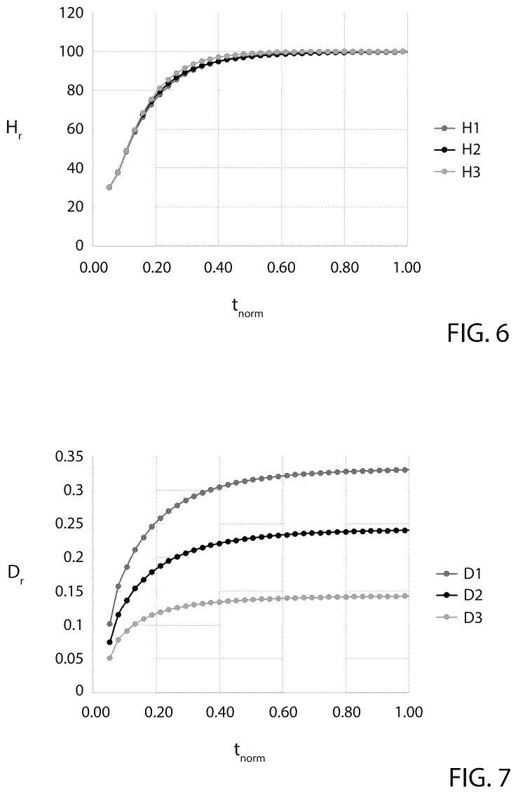

Under these conditions, the humidity trend detected in three points of the cap 32 and the corresponding displacement of three points of the sensor die 31 underlying the three points where the relative humidity Hr has been extracted have been simulated, as shown in FIG. 6 (showing curves of relative humidity Hr—H1, H2, H3—as a function of the normalized time tₙₒᵣₘ) and in FIG. 7 (relative deformation measures Dᵣ—D1, D2, D3—).

These simulations have been repeated on multiple MEMS devices 20, 120 and have demonstrated the existence of a significant correlation between the signal measured by the humidity sensor 30 and the deformation of the MEMS device 20 in case the humidity time constant (τₕ) and the device deformation time constant (τ_{def}) are approximately similar.

Further studies have also shown that similar trends of the humidity time constant and of the deformation are obtained when the volume of the packaging mass 25 of the MEMS device 20, 120 (possibly including also the humidity sensitive layer 121 is comprised between about 30% and 50% of the total volume of the MEMS device 20, 120, i.e., indicating the volume of the packaging mass 25 as Vᵣ and the total volume of the MEMS device 20, 120 as Vₜₒₜ, it is:

$$0.3 < {V}_{r /} {V}_{tot} < 0.5 . \qquad ( 1 )$$

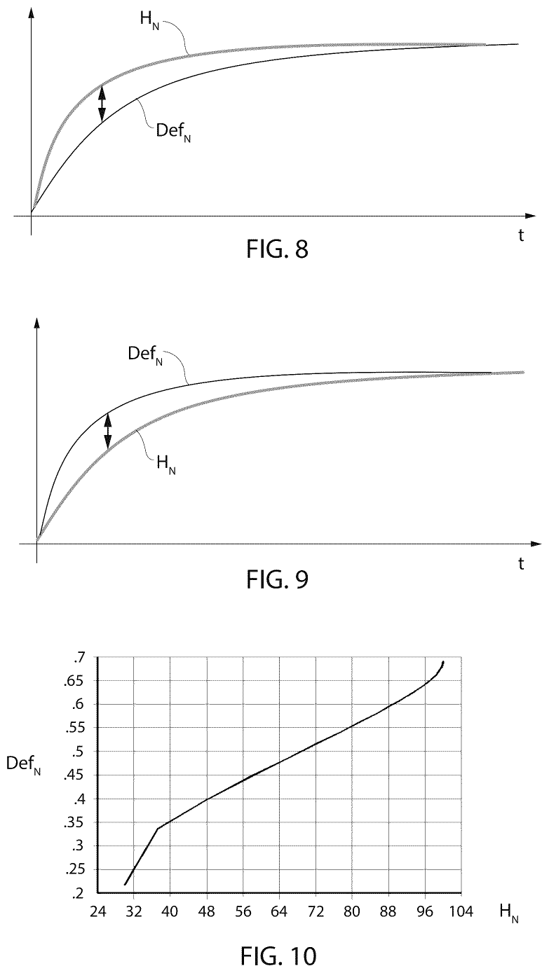

In fact, it has been seen that, when the ratio Vᵣ/Vₜₒₜ is lower than 30%, the humidity signal measured by the humidity sensor 30 reaches a steady state very quickly, before the deformation of the MEMS device 20 occurs, see FIG. 8. This behavior has been interpreted as due to the fact that the amount of water that penetrates the packaging mass 25 from the top of the MEMS device 20 quickly reaches the humidity sensor 30 and saturates it immediately.

Furthermore, it has been seen that, when the volume of the packaging mass 25 Vᵣ is greater than 50% of the total volume Vₜₒₜ, the humidity signal measured by the humidity sensor 30 follows the deformation variation with a delay, see FIG. 9. This behavior has been interpreted as due to the fact that the deformation is caused by to the drops that penetrate from the sides of the MEMS device 20 rather than from the top where the humidity sensor 30 is located, thereby the latter registers the increase in humidity with a delay with respect to the amount of drops that penetrate the packaging mass 25 and cause the deformation.

In both cases, when the packaging mass 25 is too small or too large compared to the dimensions of the MEMS device 20, 120, the humidity measures do not correctly and promptly represent the deformation and therefore are not a reliable index usable in the compensation, at least in some operating conditions.

Conversely, within the range defined by the relationship (1), the studies by the Applicant have shown that the average displacement measured as a function of humidity has an approximately linear trend, as shown in FIG. 10 where Def_{N} represents the normalized deformation and H_{N} indicates the normalized humidity, in arbitrary units.

Under such conditions, a reliable compensation of the drift of the measure signal provided by the MEMS die 24, for example the angular speed value measured by the gyroscope G and/or the acceleration measured by the accelerometer XL, may be carried out.

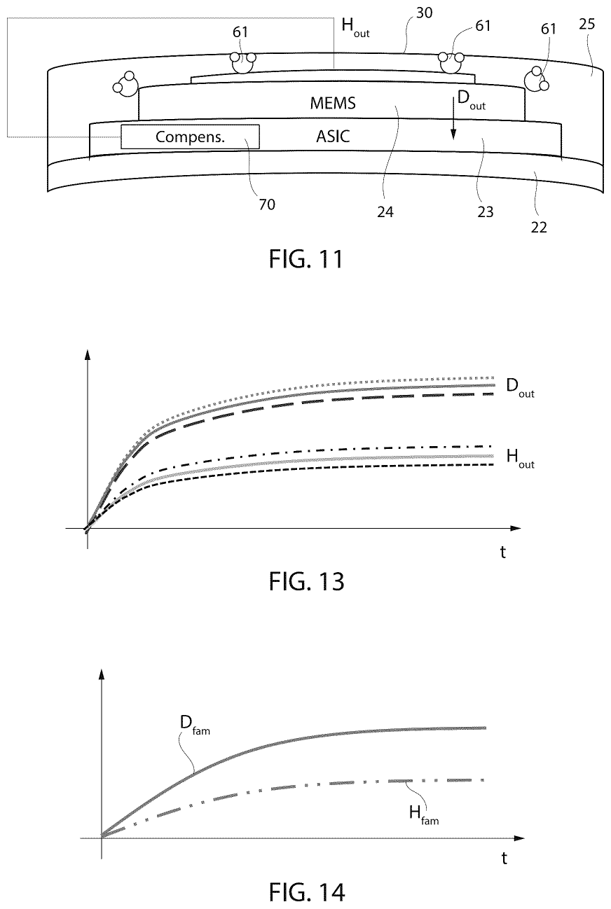

FIG. 11 schematically shows a MEMS device 20, which deforms due to the presence of water droplets (still indicated by 61). The humidity information obtainable through the humidity sensor 30 (humidity signal Hₒᵤₜ) is provided to a compensation part 70 formed in the ASIC die 24.

The compensation part 70 also receives the measure results of the inertial sensors implemented in the MEMS die 23 (measure signals Dₒᵤₜ) and compensates the values measured on the basis of the humidity signal Hₒᵤₜ, as described in detail below.

It should be noted that the humidity signal Hₒᵤₜ does not directly represent the existing humidity value but, as indicated above, measures the capacitance variation between the groups of electrodes 38, 39; however, since this is uniquely correlated to humidity, as discussed above, hereinafter the term “humidity signal Hₒᵤₜ” means a humidity signal, which is uniquely correlated to the measured humidity and may be used directly for compensation, as discussed in detail below.

Studies by the Applicant have also shown that the single MEMS devices 20, 120 have similar, but not exactly coincident, trends in the humidity-displacement correlation, due to manufacturing tolerances of the MEMS die 23 and/or differences in the mounting parameters of the dice 23, 24 to the support 22 and/or other factors.

For allowing the MEMS device 20, 120 to operate reliably under all work conditions, according to an aspect of the present disclosure, an initial calibration procedure is performed, executed at assembling batch level on a series of MEMS devices 20 during the final test step.

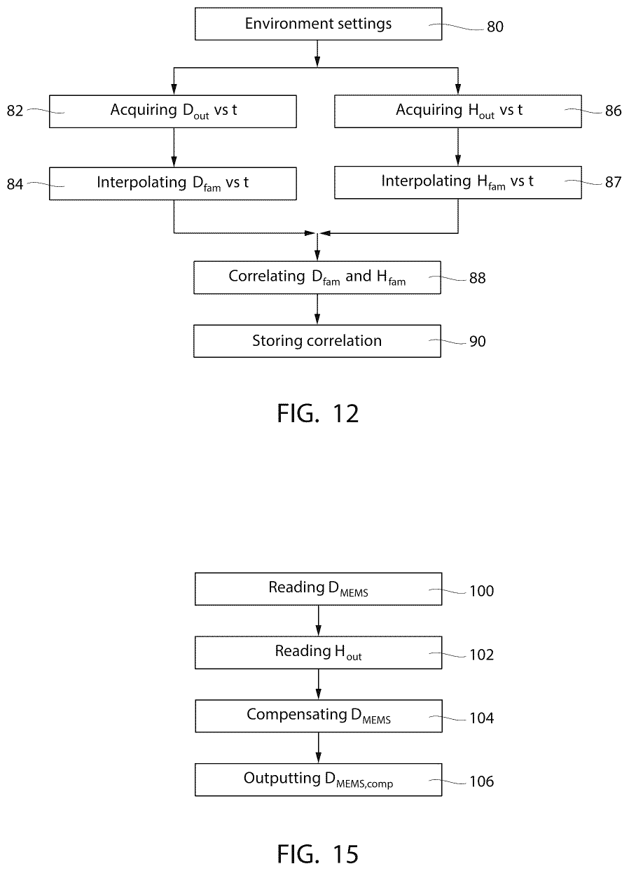

In detail, the calibration procedure, see FIG. 12, is performed by introducing a plurality of MEMS devices 20, 120 in a controlled humidity environment, where water drops are gradually introduced, so as to have a gradual and controlled increase in the humidity level, block 80.

During the calibration procedure, the MEMS devices 20 are maintained without external accelerations (apart from gravity), for measuring for example the ZRL—Zero Rate Level—value of the gyroscopes or the ZGO—Zero Gravity Offset—value of the accelerometers.

During the humidity increase step, the calibration system (not shown, typically an external calibration apparatus coupled to the ASIC die 23) acquires the measures Dₒᵤₜ of the tested MEMS devices 20, 120, block 82; performs an interpolation of the acquired measures Dₒᵤₜ, block 84; acquires the humidity information (humidity signals Hₒᵤₜ) provided by the humidity sensors 30 of each tested MEMS device 20, block 86; and performs an interpolation of the humidity signals Hₒᵤₜ, block 87.

For example, in block 82, the calibration system (not shown) samples the measure signals Dₒᵤₜ (whose plots over time are shown for sake of illustration in FIG. 13) and, in block 86, simultaneously samples the humidity signals Hₒᵤₜ generated by the respective humidity sensors 30 (whose plots over time are also shown for sake of illustration in FIG. 13).

It should be noted that the measure signals Dₒᵤₜ sampled and acquired by the calibration system (not shown) represent the outputs of the MEMS dice 24, not yet processed by the respective ASIC dice 23.

Furthermore, in block 84, the measure signals Dₒᵤₜ, sampled at the same instant in the different tested MEMS devices 20, 120, are interpolated to obtain an average trend of the family of tested MEMS devices 20, 120, as shown for example in FIG. 14 (curve of the measure interpolated values D_{fam}).

For example, the interpolation may comprise the calculation of the average value among the samples of the measure signals Dₒᵤₜ acquired at the same instant, or other suitable type of interpolation.

Similarly, in block 86, the corresponding samples of the humidity signal Hₒᵤₜ are acquired and, in block 87, interpolated humidity values H_{fam} are calculated (FIG. 14).

The acquisition step of the samples of the measure signals Dₒᵤₜ and the corresponding humidity signals Hₒᵤₜ as well as interpolation step (blocks 82-87) are carried out for a predetermined time, for example as long as the acquired samples have significant variability, or for a predetermined time, for example a few hours.

At the end of the steps of blocks 82-87, the calibration system (not shown) creates a correlation between the measure interpolated values D_{fam} and the interpolated humidity values H_{fam}, associating the relative values, block 88, and then stores the correlation, block 90, for example in a table stored in the ASIC dice 23 of the tested MEMS devices 20, 120.

The interpolated values D_{fam} may then be used as corrective factors of the measures carried out during real-time operation of each MEMS device 20, 120 as shown in the flow chart of FIG. 15.

In detail, during real-time operation, in each single MEMS device 20, 120, the compensation part 70 acquires a real-time measure value D_{MEMS} from the die 24, according to the desired operating modes, block 100; acquires the corresponding value of the humidity signal Hₒᵤₜ, provided by the humidity sensor 30, block 102; performs the compensation of the real-time measure value D_{MEMS} just acquired on the basis of the compensation value D_{fam} stored at the same value of the acquired humidity signal Hₒᵤₜ, block 104, obtaining a compensated value D_{MEMS,comp}; and, possibly after further processing of the compensated signal by the ASIC die 23, according to the foreseen procedures, sends the thus obtained compensated value D_{MEMS,comp} outside the MEMS device 20, 120, block 106.

The MEMS device, the calibration method and the operating method described herein have numerous advantages.

The humidity sensor 30 may be formed directly on the cap 32 of the MEMS die 24 using established micromanufacturing techniques and thus in an inexpensive and reliable manner.

The integrated manufacture of the humidity sensor 30 within the MEMS device 20, 120 allows for a simplified design, which also favors a possibility for real-time performance compensation.

The described MEMS device has high sensitivity thanks to the maximization of the capacity obtainable with the humidity sensor 30 formed directly on the cap, in particular when a drop of humidity rests on the electrodes, also by virtue of the small dimensions of the gap (obtainable through lithographic processes) between the electrodes 38, 39.

The pattern of the electrodes 38, 39 is highly customizable due to the high flexibility of the obtainable geometry, by simply modifying the photolithographic mask defining the groups of electrodes 33, 35.

The sensitivity of the humidity sensor may be easily tailored to the MEMS applications/sensors implemented in the MEMS die 24, increasing the adaptability of the MEMS device to the needs of the user/customer.

Finally, it is clear that modifications and variations may be made to the packaged MEMS device, the calibration method and the operating method described and illustrated herein without thereby departing from the scope of the present invention, as defined in the attached claims.

For example, the support 22 might be absent and/or the type of package might be different, for example of the QFN type with a different substrate.

As indicated above, the number, shape and dimensions of the electrodes 38, 39 may vary.

The acquisition of the humidity value Hₒᵤₜ during the calibration step, block 80, may be carried out on a single device 20, 120.

1-15. (canceled)

16. A packaged MEMS device, comprising:
a MEMS die of semiconductor material, including a sensor body and a cap mutually bonded, the sensor body incorporating at least one MEMS component;
a humidity sensor, extending on the cap and including a first and a second group of electrodes, the first and second groups of electrodes facing each other and capacitively coupled, configured to provide a humidity signal; and
a packaging mass, of electrically insulating material, surrounding the MEMS die and the humidity sensor,
wherein the first and the second groups of electrodes each comprise at least one electrode.

17. The packaged MEMS device according to claim 16, wherein the first and the second groups of electrodes each comprise a plurality of mutually interdigitated electrodes.

18. The packaged MEMS device according to claim 16, wherein the first and the second groups of electrodes are of metal.

19. The packaged MEMS device according to claim 16, further comprising a humidity sensitive layer covering the humidity sensor and extending between the humidity sensor and the packaging mass.

20. The packaged MEMS device according to claim 19, wherein the packaging mass comprises resin and the humidity sensitive layer comprises polyimide.

21. The packaged MEMS device according to claim 16, wherein a volume ratio Vᵣ/Vₜₒₜ meets the following relationship:
$$0.3 < {V}_{r} / {V}_{tot} < 0.5 ,$$
wherein Vᵣ is a volume of the packaging mass and Vₜₒₜ is a total volume of the packaged MEMS device.

22. The packaged MEMS device according to claim 16, further comprising a processing die integrating a processing unit, wherein the sensor body is bonded to the processing die and the first and the second groups of electrodes are connected to the processing unit.

23. The packaged MEMS device according to claim 22, wherein the first and the second groups of electrodes are coupled each to a respective sensor pad arranged on the cap, the processing die comprises processor pads, and the sensor pads are coupled to the processor pads of the processing die.

24. The packaged MEMS device according to claim 23, wherein the sensor pads are coupled to corresponding MEMS pads arranged on the sensor body, the processing die comprises ASIC pads, and the MEMS pads are coupled to the ASIC pads, wherein the coupling between the sensor pads, the MEMS pads and the ASIC pads is a wire coupling.

25. The packaged MEMS device according to claim 22, wherein the processing unit comprises a calibration unit, wherein the calibration unit comprises:
means for acquiring a MEMS signal from the MEMS die;
means for acquiring a humidity signal from the humidity sensor; and
means for compensating the MEMS signal on the basis of the humidity signal.

26. The packaged MEMS device according to claim 16, wherein the MEMS component is an inertial sensor.

27. A method for calibrating a packaged MEMS device, comprising:
providing a packaged MEMS device that includes a MEMS die formed of semiconductor material, a humidity sensor extending on a cap of the MEMS die, and a packaging mass surrounding the MEMS die and the humidity sensor;
introducing the packaged MEMS device into an environment with a humidity level;
gradually modifying a humidity level in the environment;
capacitively measuring humidity changes between a first group of electrodes and a second group of electrodes of the humidity sensor while gradually modifying the humidity level;
acquiring an output signal from the MEMS die of the packaged MEMS device while gradually modifying the humidity level;
generating a correlation between the acquired output signal and the measured humidity changes; and
storing the correlation for use in compensating the output signal during operation of the packaged MEMS device.

28. The method according to claim 27, wherein the humidity sensor comprises:
the first group of electrodes and the second group of electrodes, the first and second groups of electrodes being interdigitated and capacitively coupled to detect humidity changes.

29. The method according to claim 27, further comprising:
maintaining the packaged MEMS device without external accelerations, apart from gravity, during the calibration.

30. The method according to claim 27, wherein the packaging mass comprises resin, and the humidity sensor is covered by a humidity-sensitive layer comprising polyimide.

31. The method according to claim 27, wherein the correlation is generated when a humidity time constant and a device deformation time constant are approximately similar.

32. The method according to claim 27, wherein the correlation between the output signal and the measured humidity changes is stored in a table within a processing unit of the packaged MEMS device.

33. A method for calibrating a plurality of packaged MEMS devices, the method comprising:
providing a plurality of MEMS devices, each including a MEMS die of semiconductor material, a humidity sensor extending on the MEMS die, and a packaging mass surrounding the MEMS die and the humidity sensor;
introducing the plurality of MEMS devices into an environment with a controlled humidity level;
gradually modifying a humidity level in the environment;
acquiring output signals from the MEMS die of the plurality of MEMS devices while gradually modifying the humidity level;
acquiring humidity signals from the humidity sensors of the plurality of MEMS devices while gradually modifying the humidity level;
interpolating the output signals and humidity signals to obtain average trends for the plurality of MEMS devices; and
storing a correlation between the interpolated output signals and interpolated humidity signals.

34. The method according to claim 33, wherein each MEMS device includes a humidity sensor formed on a cap of the MEMS die, the cap being bonded to a sensor body of the MEMS die.

35. The method according to claim 33, wherein the plurality of MEMS devices have similar but not exactly coincident trends in humidity-displacement correlation due to manufacturing tolerances.

36. The method according to claim 33, wherein the interpolating comprises calculating average values among samples of the output signals acquired at a same instant.

37. The method according to claim 33, wherein the gradually modifying the humidity level comprises introducing water drops gradually to create a gradual and controlled increase in the humidity level.

38. The method according to claim 33, wherein each MEMS device includes a packaging mass with a volume ratio Vr/Vtot that satisfies the relationship 0.3<Vr/Vtot<0.5, where Vr is a volume of the packaging mass and Vtot is a total volume of the MEMS device.

39. A method for compensating an output signal of a packaged MEMS device, the method comprising:
providing a packaged MEMS device that includes a MEMS die of semiconductor material, a humidity sensor extending on the MEMS die, and a packaging mass surrounding the MEMS die and the humidity sensor;
acquiring an output signal from a sensor body of the MEMS die during operation of the packaged MEMS device;
acquiring a humidity signal from the humidity sensor during operation of the packaged MEMS device; and
compensating the output signal on the basis of the humidity signal using a stored correlation between the output signal and the humidity signal.

40. The method according to claim 39, wherein acquiring the humidity signal comprises:
detecting capacitance variations between a first group of electrodes and a second group of electrodes of the humidity sensor of the packaged MEMS device.
